(19) United States
(12) Patent Application Publication
(10) Pub. No.: US 2020/0337155 A1
(43) Pub. Date: Oct. 22, 2020

(54) METHOD FOR FORMING LAMINATED STRUCTURE OF TOUCH PANEL

(71) Applicants: Interface Technology (ChengDu) Co., Ltd., Chengdu City (CN); Interface Optoelectronics (ShenZhen) Co., Ltd., Shenzhen City (CN); General Interface Solution Limited, Miaoli County (TW)

(72) Inventor: Han Lung TSAI, Miaoli County (TW)

(21) Appl. No.: 16/411,511

(22) Filed: May 14, 2019

(30) Foreign Application Priority Data
Apr. 18, 2019 (CN) 201910313404.9

(51) Int. Cl. H05K 3/18; C23C 18/20; H05K 3/00

(52) U.S. Cl. CPC H05K 3/182; G06F 2203/04103; H05K 3/0058; C23C 18/2086

(57) ABSTRACT

A method for forming a laminated structure of a touch panel, the method comprising: after forming a metal line and a bridge line, adding a metallization additive, and metallizing plating the metal line and the bridge line. The present invention is applied to a transparent conductive layer with bridge lines, metal lines, and T-bar. The metal line and the bridge line are fabricated in the same layer, which can reduce the processes and reduce the material cost, and the metallization plating after forming can reduce the stretching effects of the conductive material.

### BACKGROUND OF THE INVENTION

### Field of the Invention

The present invention relates to a method for forming a laminated structure of a touch panel, and more particularly to a method for manufacturing a metal trace and a bridge by using a metallization plating method when the touch panel is formed.

### Description of the Prior Art

According to the conventional touch panel, when the conductive layer is made, the metal trace or metal line and the bridge circuit are formed by photolithography. The forming of the bridging lines and metal lines results in more procedures, and the cost cannot be reduced.

Moreover, the metal lines and the bridging lines are reshaped after being fabricated, and it is easy to have the risk of disconnection in a large stretched area and the transparent conductive material used as a bridge line structure or bridge circuit stack while forming and stretching. As a result there will be problems with high impedance, which may lead to electrical abnormalities in the product.

As shown, there are many shortcomings in the conventional method and device that need to be overcome in order to improve the product.

### SUMMARY OF THE INVENTION

In view of the above, an object of the present invention is to provide a method of forming a laminated structure for a touch panel. The touch panel is based on production of the conductive layer, metallized plating to fabricate a metal trace and a bridge. The circuitry enables the metal traces, metal line, or metal circuit and the bridge to be fabricated in the same layer, which can reduce the processes and reduce the material cost, and the metallization after forming can reduce the high impedance caused by the stretching of the conductive material.

According to the above object, a method for molding a laminated structure of a touch panel of the present invention comprises the steps of: firstly providing a base layer on which a pattern structure is pre-marked; forming a transparent conductive layer on the pattern structure, forming an insulating pattern structure on the transparent conductive layer; then forming a photosensitive resin coating layer on the transparent conductive layer and the insulating pattern structure, defining a metal trace and bridge of the circuit pattern structure on the photosensitive resin coating layer, forming a metal line and bridge circuit in relation to the pattern structure; then adding a metal additive; finally, in the base layer, the transparent conductive layer, the insulating pattern structure, the metal line and the bridge line are covered with a photosensitive film protective layer (OC protective layer); characterized in that after the metal line and the bridging line are formed, and before the metallization additive is added, metallization is used to metallize plate the metal line and the bridge line; thus, the metal trace and the metal line width of the bridge line after metallization plating is wider than the side of the photosensitive resin coating layer by about 2˜4 μm, and the widened region is designed as an overlapping area and applied to the transparent conductive layer and metal lines, bridge lines, and T-bar overlapping, and the metal lines and the bridge lines are fabricated in the same layer, which can reduce the processes and reduce the material cost, and the metallization plating after molding can reduce the high impedance caused by the stretching of the conductive material.

### BRIEF DESCRIPTION OF THE DRAWINGS

FIG. 1 is a process flow diagram of the method of forming the laminated structure of the touch panel according to an embodiment of the present invention;

FIG. 2 is a schematic plan view of the laminated structure of the touch panel according to an embodiment of the present invention.

FIG. 3 is a schematic plan view of a metal wiring layer and the conductive bridge of the touch panel according to an embodiment of the present invention;

FIG. 4 is a plan view illustrating the conductive layer bridges of the laminated structure of the touch panel according to an embodiment of the present invention; and

FIG. 5 is a drawing illustrating the laminated structure of the touch panel aperture (VIA Type) type and island-type (Island Type).

### DESCRIPTION OF THE PREFERRED EMBODIMENTS

To further understand and understand the purpose, shape, structure and function of the present invention, the present invention will be described in detail as follows:

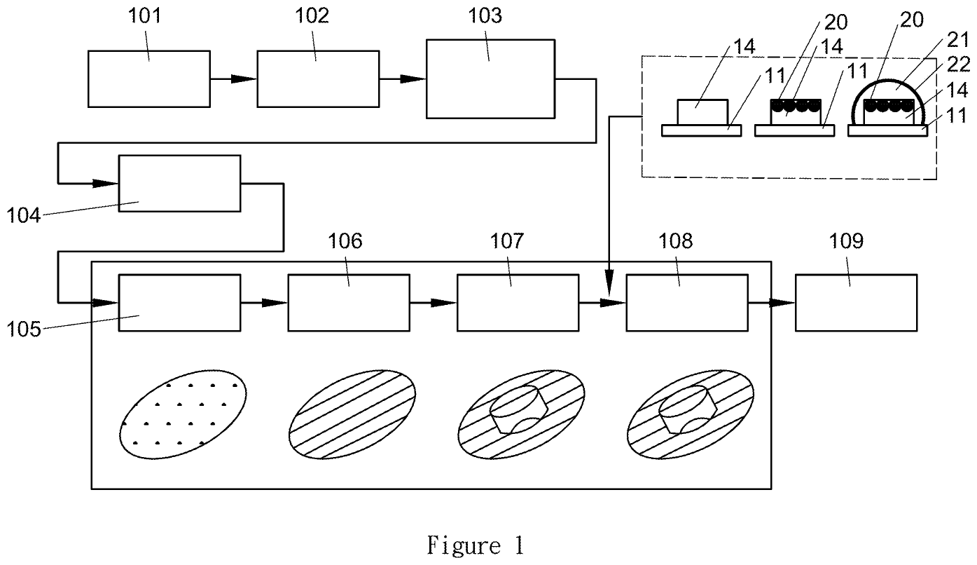

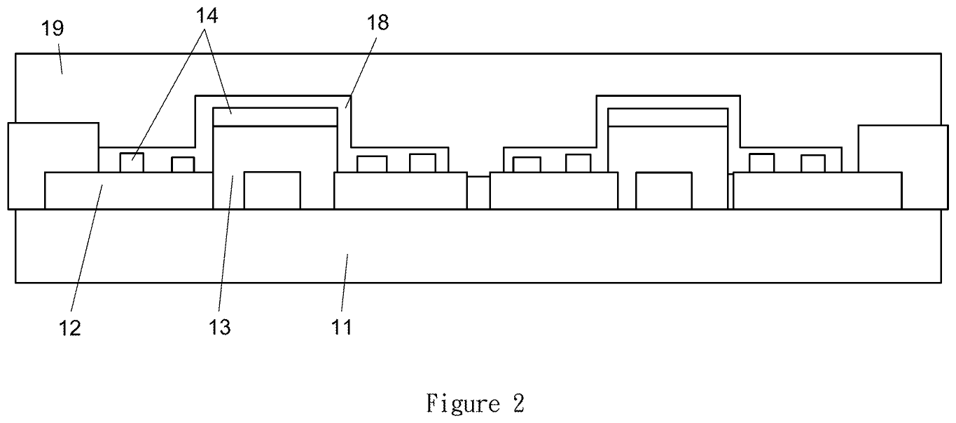

The present invention relates to a method for forming a laminated structure of a touch panel. Referring to FIGS. 1, 2, and 3, a method for forming a laminated structure of a touch panel of the present invention comprises the following steps:

Step 101: providing a base layer 11;

Step 102: pre-marking a pattern structure on the base layer 11;

Step 103: forming a transparent conductive layer 12 on the pattern structure;

Step 104: forming an insulating pattern structure 13 on the transparent conductive layer 12;

Step 105: forming a photosensitive resin coating layer 14 on the transparent conductive layer 12 and the insulating pattern structure 13;

Step 106: defining the photosensitive resin layer 14 covering a metal trace or metal line pattern structure and the bridge line;

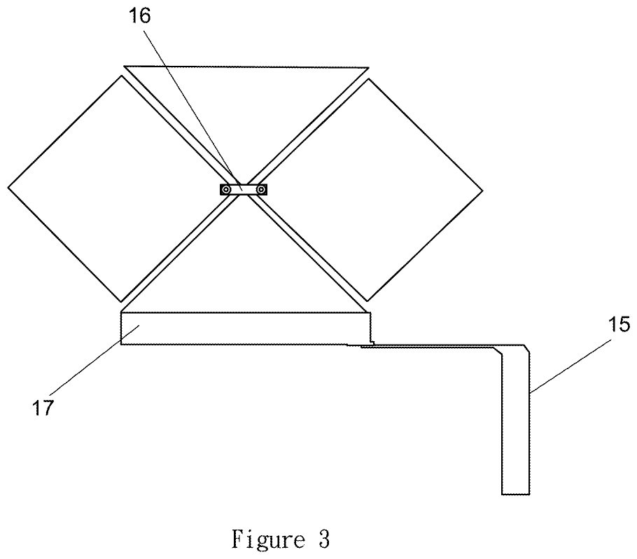

Step 107: forming a metal line 15 and a bridge line 16 in the pattern structure, and forming a T-bar 17 (as shown in FIG. 3);

Step 108: adding a metallization additive 18;

Step 109: coating a light-sensitive film protective layer (OC (Over Coat) protective layer) 19 on the base layer 11, the transparent conductive layer 12, the insulating pattern structure 13, the metal line 15, and the bridge line 16.

It is characterized in that after the metal line 15 and the bridge line 16 are formed in step 107, and before the step of adding the metallization additive 18, the metal line 15 is metallized and the bridge line 16 is metallized.

Thereby, after the metallization, the metal line 15 and the bridge line 16 have a width wider than the single side of the photosensitive resin coating layer 14 by about 2 to 4 μm, and the widened area is designed as a metal overlapping area, which can be applied to the transparent conductive layer and the bridge line 16 and the metal line 15 and the T-bar 17 are overlapped (as shown in FIG. 3). The metal line 15 and the bridge line 16 are fabricated in the same layer to reduce the processes.

Reducing the material cost and the metallization plating after forming reduces the high impedance caused by the stretching of the conductive material.

Referring to FIGS. 1, 2, and 3, in the step of metallizing the metal line 15 and the bridge line 16, a catalyst 20 (such as palladium (Pd)) is added to the photosensitive resin coating layer 14 of the base layer 11. The catalyst 20 is adsorbed in the metallization plating process, and the metallized metal 21 (for example, copper (Cu)) is formed on the metal line 15 and the bridge line 16 of the photosensitive resin coating layer 14. The metallized metal and a surface blackening 22 are covered by a metal (overlay).

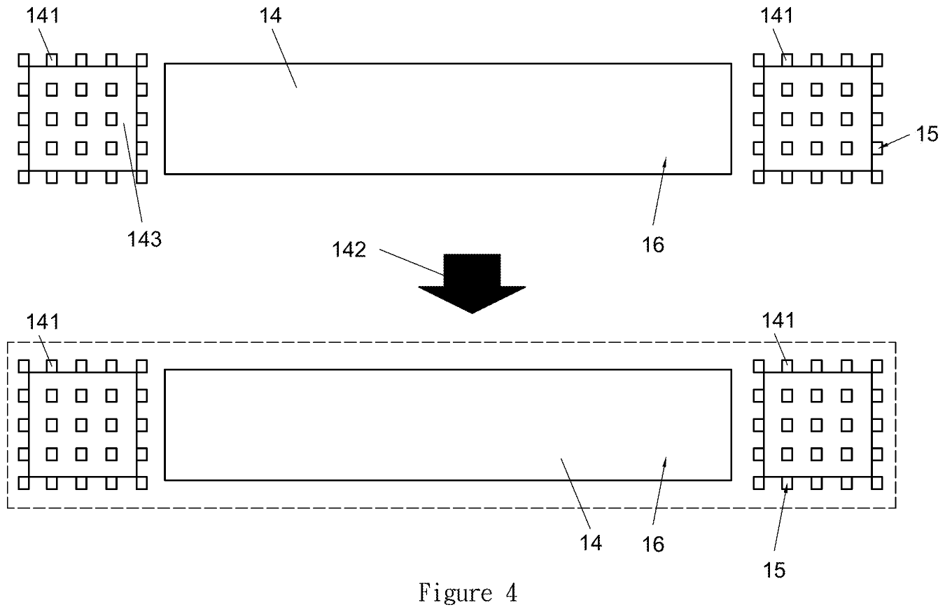

Referring to FIGS. 1, 2, 3, and 4, the pattern of the metal trace and the bridge line defined by the photosensitive resin coating layer 14 are designed as an array 141, after metallization 142 is applied. The metal line 15 and the bridge line 16 increase the metal overlap contact area after the metallization plating 142.

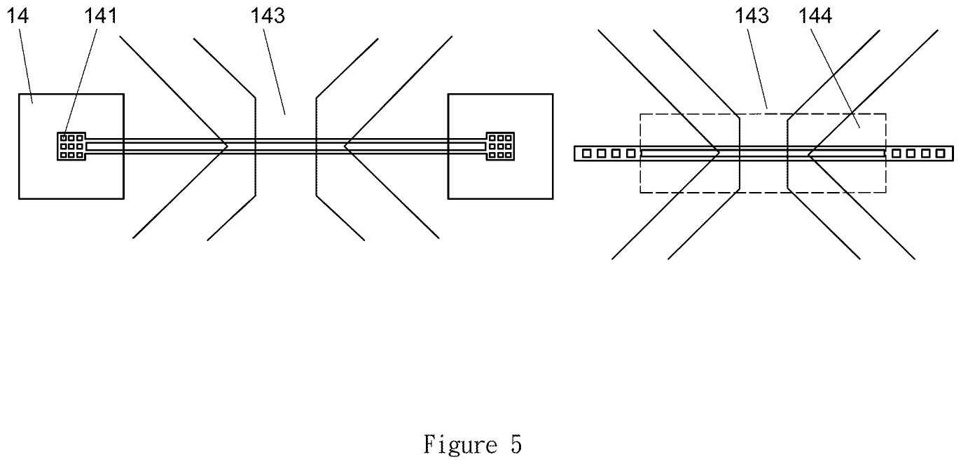

Referring to FIGS. 1, 2, 3, 4, and 5, in the pattern structure of the array 141 of the photosensitive resin coating layer 14, the VIA opening 143 may be designed to be larger than the line of the array 141 and the island. The overlap of the Island Type electrode 144 reduces the effects of the overlap offset.

Referring to FIGS. 1, 2, 3, 4, and 5, the thickness of the metallization 142 is 1000˜3000 nm, which is thicker than the general sputtering metal (thickness of 100˜200 nm), which can improve the metal line climbing slope problem.

Referring to FIGS. 1, 2, 3, 4, and 5, the photosensitive resin coating layer 14 is a stretchable insulating material having an elongation of >150%.

Referring to FIGS. 1, 2, 3, 4, and 5, the transparent conductive layer 12 comprises a conductive polymer (PEDOT) conductive material, a carbon nanosphere (CNB) conductive material, or a nano silver wire (AgNW).

Referring to FIGS. 1, 2, 3, 4, and 5, the base layer 11 comprises a stretchable material such as a plastic PC material, a plastic PET material, a plastic PMMA material, or the like.

In summary, the method for forming the laminated structure of the touch panel of the present invention comprises an unprecedented innovative structure, which is not found in any publication, and there is no similar product on the market, so that it has novelty. In addition, the unique features and functions of the present invention are far from comparable to the conventional ones, so it is indeed more progressive than the conventional ones.

The above description is only the best embodiment of the present invention, but the structural features of the present invention are not limited thereto, and any change or modification that can be easily considered by those skilled in the art can be covered.

What is claimed is:

1. A method for forming a laminated structure of a touch panel, the method comprising:
providing a base layer;
pre-marking a pattern structure on the base layer;
forming a transparent conductive layer on the pattern structure;
forming an insulating pattern structure on the transparent conductive layer;
forming a photosensitive resin coating layer on the transparent conductive layer and the insulating pattern structure;
defining a metal line and a bridge line pattern structure on the photosensitive resin coating layer;
forming a metal line and a bridge line in the pattern structure;
adding a metallization additive;
coating a light-sensitive film protective layer on the base layer, the transparent conductive layer, the insulating pattern structure, the metal line, and the bridge line;
Wherein after forming the metal line and the bridge line and prior to adding the metallization additive, metal plating the metal line and the bridge line.

2. The method of forming the laminated structure of the touch panel of the scope of claim 1, wherein after the metallization, the metal line and the bridge line have a width wider than a side of the photosensitive resin coating layer by 2˜4 μm.

3. The method for forming a laminated structure of a touch panel according to claim 1, wherein in the step of metallizing the metal line and the bridging line, a catalyst is added to the photosensitive resin coating layer of the base layer, the catalyst is adsorbed in the metallization plating process, and the metallized metal is copper.

4. The method for forming a laminated structure of a touch panel according to claim 3, wherein the catalyst is palladium (Pd).

5. The method for forming a laminated structure of a touch panel according to claim 1, wherein the patterned structure of the metal line and the bridge line defined by the photosensitive resin coating layer is designed as an array, and after metallization the metal line and the bridge line increase metal contact area.

6. The method for forming a laminated structure of a touch panel according to claim 5, wherein in the array pattern structure of the photosensitive resin coating layer, a VIA opening is larger than the array, and an Island Type electrode is used to reduce overlap effects.

7. The method for forming a laminated structure of a touch panel according to claim 1, wherein the metallized metal has a thickness of 1000 to 3000 nm.

8. The method for forming a laminated structure of a touch panel according to claim 1, wherein the photosensitive resin coating layer is a stretchable insulating material and has an elongation of >150%.

9. The method for forming a laminated structure of a touch panel according to claim 1, wherein the transparent conductive layer is a conductive polymer (PEDOT) conductive material, a carbon nanosphere (CNB) conductive material, or a nano-layer silver wire (AgNW) conductive material.

10. The method for forming a laminated structure of a touch panel according to claim 1, wherein the base layer is a plastic PC material, a plastic PET material, or a plastic PMMA material.
